(19) United States
(12) Patent Application Publication
(10) Pub. No.: US 2014/0213003 A1
(43) Pub. Date: Jul. 31, 2014

(54) GAN TYPE LIGHT EMITTING DIODE DEVICE AND METHOD OF MANUFACTURING THE SAME

(71) Applicant: SAMSUNG ELECTRONICS CO., LTD., Suwon-si (KR)

(72) Inventors: Kun Yoo KO, Hwaseong-si (KR); Young June JEONG, Seoul (KR); Seung Hwan CHOI, Suwon-si (KR); Seong Ah JOO, Seoul (KR); Jung Kyu PARK, Seoul (KR)

(73) Assignee: SAMSUNG ELECTRONICS CO., LTD., Suwon-si (KR)

(21) Appl. No.: 14/228,967

(22) Filed: Mar. 28, 2014

Related U.S. Application Data
(62) Division of application No. 12/207,615, filed on Sep. 10, 2008.

(30) Foreign Application Priority Data
Sep. 27, 2007 (KR) 10-2007-0097219

(51) Int. Cl. H01L 33/00; H01L 33/48; H01L 33/32

(52) U.S. Cl. CPC H01L 33/0075; H01L 33/32; H01L 33/486
USPC 438/27

(57) ABSTRACT

The present invention relates to a GaN type LED device and a method of manufacturing the same. More particularly, there are provided a GaN type LED device including an LED chip; and a submount eutectic-bonded with the LED chip through an adhesive layer, wherein the adhesive layer is configured by soldering a plurality of metallic layers in which a first metallic layer and a second metallic layer are sequentially stacked, and the second metallic layer is formed in a paste form. Further, the present invention provides a method of manufacturing the GaN type LED device.

### CROSS-REFERENCE TO RELATED APPLICATIONS

This application claims the benefit of Korean Patent Application No. 10-2007-0097219 filed with the Korea Intellectual Property Office on Sep. 27, 2007, the disclosure of which is incorporated herein by reference.

### BACKGROUND OF THE INVENTION

1. Field of the Invention

The present invention relates to a GaN type light emitting diode device; and more particularly, to a GaN type light emitting diode device and a method of manufacturing the same which can stabilize a thermal property in a process of die-attaching an LED chip and a submount to each other.

2. Description of the Related Art

In general, III-V nitride semiconductors including GaN type, and the like are widely used for a green or blue light emitting diode (hereinafter, referred to as an ‘LED’) device provided as a light source to a full-color display, an image scanner, various signal systems, and an optical communication apparatus excellent physical and chemical characteristics. Such LED device generates light in an active layer using a recombination principle of electrons and holes and emits the generated light.

Recently, high luminance is required in order to use such GaN type LED device as an illumination source and a high-output GaN type LED device which can operate at a large current is fabricated in order to achieve the high luminance.

Such GaN type LED device is classified into a laterally structured light emitting diode and a vertically structured light emitting diode.

The laterally structured GaN type LED device is classified into a top emitting light emitting diode and a flip-chip light emitting diode.

The top emitting light emitting diode is formed to emit light through an ohmic electrode layer being in contact with a p-type nitride semiconductor layer and the flip-chip light emitting diode is formed to emit the light through a sapphire substrate.

Meanwhile, such GaN type LED device is generated die-attached onto a submount (or a package or a lead frame: hereinafter, referred to as a ‘submount’). The light is extracted and is emitted through on one surface of an LED chip which is not die-attached onto the submount.

Hereinafter, referring to FIG. 1, a flip chip type LED device among conventional GaN type LED devices will hereinafter be described in detail.

FIG. 1 is a schematic cross-sectional view of the conventional GaN type LED device.

As shown in FIG. 1, the conventional GaN type LED device includes an LED chip 100 having a pair of electrodes, a submount 200, and an adhesive layer 300 for flip-bonding the LED chip 100 and the submount 200 to each other.

Meanwhile, the conventional adhesive layer 300 is composed of a transparent epoxy or a paste such as Ag, or the like

In other words, in the conventional GaN type LED device, the adhesive layer 300 composed of the transparent epoxy or the paste such as Ag, or the like is reflowed, thereby bonding the LED chip 100 and the submount 200 to each other.

### SUMMARY OF THE INVENTION

However, when the transparent epoxy is used as the adhesive layer, a thermal resistance is high (30 K/W or higher) and an optical characteristic is deteriorated due to yellowing by short-wavelength light and when the silver paste is used as the adhesive layer, a leaked current is generated due movement of silver, thereby deteriorating a characteristic and reliability of the device.

In order to solve the above-described problems, an object of the present invention is to provide a GaN type LED device, which can a thermal resistance characteristic and reliability by applying a soldering process by using each of a plurality of metallic layers which is composed of a single element as an adhesive layer at the time of bonding an LED chip and a submount.

Another object of the invention is to provide a method of manufacturing the GaN type LED device.

In order to achieve the above-described objects, there is a provided a GaN type LED device including an LED chip; and a submount eutectic-bonded with the LED chip through an adhesive layer, wherein the adhesive layer is configured by soldering a plurality of metallic layers in which a second metallic layer and a first metallic layer are sequentially stacked and the second metallic layer is formed in a paste form.

In the GaN type LED device in accordance with the present invention, the first metallic layer may be made of the same material as the second metallic layer.

In the GaN type LED device in accordance with the present invention, the first metallic layer may be made of one or more metals selected from a group consisting of Sn, Ag, Au, and Cu.

In the GaN type LED device in accordance with the present invention, the second metallic layer may be made of an alloy containing Sn or Ag.

In the GaN type LED device in accordance with the present invention, it is preferable that the GaN type LED device further includes a transparent layer formed between the LED chip and the adhesive layer, and the transparent layer may be made of one or more oxides selected from a group consisting of NiO,ₓ TiO₂, ITO, and SiO₂, or Si₃N₄ or MgF₂.

In the GaN type LED device in accordance with the present invention, it is preferable that the GaN type LED device further includes a reflection layer formed the transparent layer and the adhesive layer, and the reflection layer may be made of an alloy containing at least one of Ag or Al.

In the GaN type LED device in accordance with the present invention, it is preferable that the GaN type LED device further includes a diffusion barrier layer formed between the reflection layer and the adhesive layer, and the diffusion barrier layer may be made of one or more metals selected from a group consisting of Ni, Pt, Cr, Ti, and W.

In the GaN type LED device in accordance with the present invention, the LED chip may include a substrate; an n-type nitride semiconductor layer formed on the substrate, which is divided into a first area and a second area; an active layer formed on the first area of the n-type nitride semiconductor layer; a p-type nitride semiconductor layer formed on the active layer; a p-type electrode formed on the p-type nitride semiconductor layer; and an n-type electrode formed on a second area of the n-type nitride semiconductor layer or may include an n-type electrode; a light emitting structure formed by stacking the n-type electrode, the n-type nitride semiconductor layer, an active layer, and a p-type nitride semiconductor layer sequentially stacked on a bottom surface of the n-type electrode; a p-type electrode formed on a bottom surface of the light emitting structure; and a structure supporting layer formed on a bottom surface of the p-type electrode.

In order to achieve another object of the present invention, there is provided a method of manufacturing a GaN type light emitting diode device including the steps of: preparing an LED chip; forming a first metallic layer on a surface opposite to a light emitting surface of the LED chip; preparing a submount; forming a second metallic layer on one surface of the submount to be bonded to the LED chip; and eutectic-bonding the first metallic layer and the second metallic layer to each other by soldering the first metallic layer and the second metallic layer, wherein the second metallic layer is formed in a paste form.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a schematic cross-sectional view of a conventional GaN type LED device;

FIG. 2 is a schematic cross-sectional view of a GaN type LED device in accordance with one embodiment of the invention;

FIG. 3 is a cross-sectional view illustrating a modified example of a GaN type LED device in accordance with one embodiment of the invention;

FIGS. 4A to 4B are process cross-sectional views sequentially illustrating a method of manufacturing a GaN type LED device in accordance with one embodiment of the invention; and

FIGS. 5 and 6 are schematic cross-sectional views of a GaN type LED device in accordance with another embodiment of the invention.

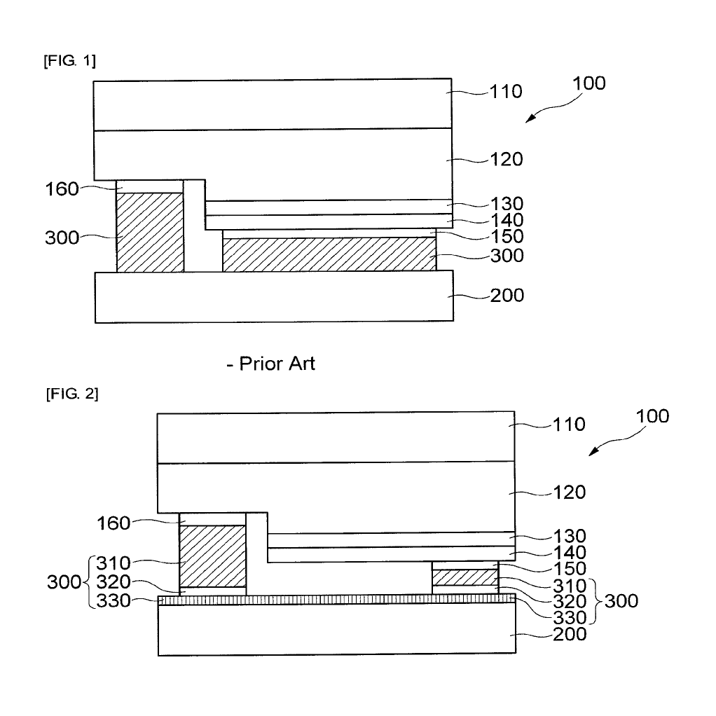

### DETAILED DESCRIPTION OF THE PREFERRED EMBODIMENTS

Reference will now be made in detail to the embodiments of the present general inventive concept, examples of which are illustrated in the accompanying drawings.

In order to clearly displaying several layers and areas, thicknesses of the layers and areas are magnified in the accompanying drawings. Like reference numerals refer to like elements throughout.

### GaN Type LED

Referring to FIG. 2, a GaN type LED device in accordance with one embodiment of the present invention will be described in detail.

FIG. 2 is a schematic cross-sectional view of a structure of the GaN type device in accordance with the one embodiment of the invention.

Referring to FIG. 2, the GaN type device in accordance with the one embodiment of the invention includes an LED chip 100, a submount 200, and an adhesive layer 300 eutectic-bonding the LED chip 100 and the submount 200 to each other.

In the LED chip 100, a buffer layer (not shown) and an n-type nitride semiconductor layer 120 are sequentially stacked on a light transmitting substrate 110. At this time, the n-type nitride semiconductor layer 120 is divided into a first area and a second area. The first area defines a light emitting surface and therefore it is preferable that a luminance characteristic of the device is improved by making a dimension of the first area larger than that of the second area.

More specifically, the substrate 110 is suitable to grow a nitride semiconductor single crystal and is preferably made of a transparent material including a sapphire. In addition to the sapphire, the substrate 110 may be made of zinc oxide (ZnO), gallium nitride (GaN), silicon carbide (SiC), and aluminum nitride (AlN).

The buffer layer serves to improve lattice matching with the substrate 110 before growing the n-type nitride semiconductor layer 120 on the substrate 110. The buffer layer may be omitted according to a process condition and a device characteristic.

The n-type nitride semiconductor layer 120 may be made of a semiconductor material having a composition formula of In_{X}Al_{Y}Ga_{1-X-Y}N (herein, 0≦X, 0≦Y, X+Y≦1). More specifically, the n-type nitride semiconductor layer 120 may be composed of a GaN layer or a GaN/AlGaN layer doped with n-type conductive impurities. The n-type conductive impurities employ Si, Ge, Sn, and the like, for example and preferably employ Si.

An active layer 130 and a P-type nitride semiconductor layer 140 are sequentially stacked on the first area of the n-type nitride semiconductor layer 120, thereby forming a light emitting structure.

The active layer 130 may be composed of an InGaN/GaN layer of a multi-quantum well structure.

The p-type nitride semiconductor layer 140 may be made of the semiconductor material having the composition formula of In_{X}Al_{Y}Ga_{1-X-Y} N (herein, 0≦X, 0≦Y, X+Y≦1). More specifically, the p-type nitride semiconductor layer 140 may be composed of a GaN layer or a GaN/AlGaN layer doped with p-type conductive impurities. The p-type conductive impurities employ Mg, Zn, Be, and the like, for example and preferably employ Mg.

A p-type electrode 150 is formed on the p-type nitride semiconductor layer 140. It is preferable that the p-type electrode 150 is composed of one or more layers selected from a reflection electrode, an ohmic contact electrode, and a transparent electrode. For example, the p-type electrode 150 may be formed of a single layer composed of any one layer selected from the reflection electrode, the ohmic contact electrode, and the transparent electrode or multilayers such as the reflection electrode/the ohmic contact electrode, the ohmic contact electrode/the transparent electrode, the ohmic contact electrode/the transparent electrode/the reflection electrode, and the like according to the process condition and the device characteristic.

An n-type electrode 160 is formed on the second area of the n-type nitride semiconductor layer 120. A part of the light emitting surface is mesa-etched and removed to form the second area of the n-type nitride semiconductor layer 120.

The submount 200 employs a silicon wafer or an AlN ceramic substrate having high thermal conductivity.

Particularly, the adhesive layer 300 in accordance with the invention has a structure in which each of a plurality of metallic layers which is composed of a single element is stacked.

More specifically, in the adhesive layer 300, first metallic layers 310 and 320, and a second metallic layer 330 are sequentially stacked from a surface opposite to the light emitting surface of the LED chip. In the embodiment, the first metallic layer is composed of two layers, but the first metallic layer is not limited to it and may be composed of a single layer.

It is preferable that the first metallic layers 310 and 320, and the second metallic layer 330 include reflection materials in order to prevent reflectivity of the submount 200 from influencing a characteristic of the LED chip 100. The first metallic layers 310 and 320, and the second metallic layer 330 may be made of the same material. For example, the first metallic layers 310 and 320, and the second metallic layer 330 may be made of a metal containing Sn or Ag.

More specifically, the first metallic layers 310 and 320 may be made of one or more metals selected from a group consisting of Sn, Ag, Au, and Cu. The second metallic layer 330 may be made of the metal containing Sn or Ag. The first metallic layers 310 and 320, and the second metallic layer 330 serve to eutectic-bond the LED chip 100 and the submount 200 to each other.

Accordingly, the GaN type LED device in accordance with the invention can stabilize a thermal property and improve reliability by minimizing occurrence of a leaked current in comparison with a conventional GaN type LED device which performs reflow bonding by using a paste or a transparent epoxy as an adhesive layer.

Since the adhesive layer is configured by soldering each of the plurality of metallic layers which is composed of the single element, thereby minimizing a change in composition ratio of an alloy, it is possible to facilitate control of the composition ratio of the alloy.

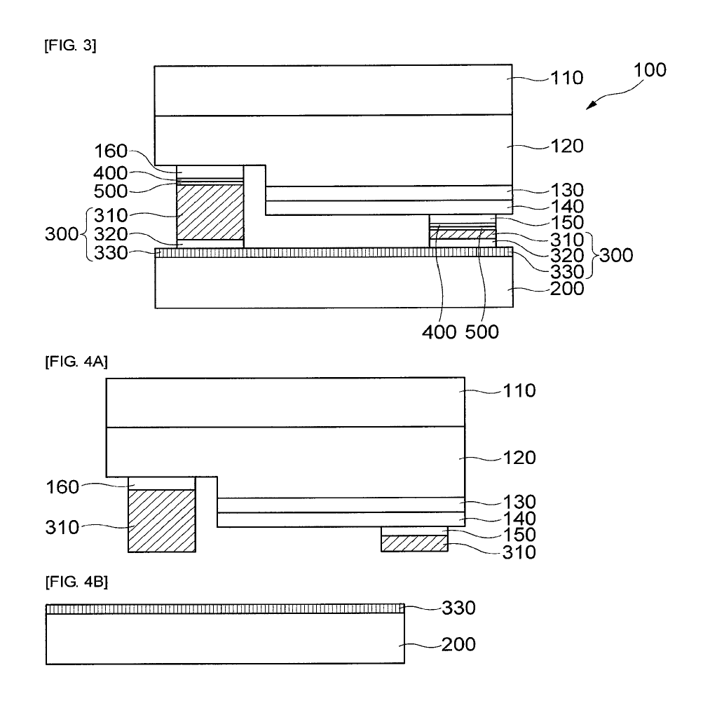

As shown in FIG. 3, it is preferable that the GaN type LED device in accordance with the invention further includes a transparent layer (not shown) and a reflection layer 400, and a diffusion barrier layer 500 for protecting the reflection layer 400 which are formed on one surface of the LED chip 100 bonded with the submount 200 to prevent light from being absorbed due to formation of an alloy of the first metallic layers 310 and 320, and the second metallic layer 330 in the adhesive layer 300.

The transparent layer may be made of one or more oxides selected from a group consisting of NiOₓ TiO₂, ITO, and SiO₂ or Si₃N₄ or MgF₂. The reflection layer 400 may be made of an alloy including at least one of Ag and Al. The diffusion barrier layer 500 may be made of one or more metals selected from a group consisting of Ni, Pt, Cr, Ti, and W.

Herein, FIG. 3 is a cross-sectional view illustrating a modified example of the GaN type LED device in accordance with the one embodiment of the invention.

### Method of Manufacturing GaN Type LED Device

A method of manufacturing a GaN type LED device in accordance with one embodiment of the invention will be described in detail with reference to FIG. 4A, FIG. 4B, and the above-described FIG. 2.

FIGS. 4A and 4B are process cross-sectional views sequentially illustrating the method of manufacturing the GaN type LED device in accordance with the one embodiment of the invention.

First, as shown in FIG. 4A, an LED chip 100 is prepared.

The LED chip 100 includes a substrate 110, an n-type nitride semiconductor layer 120 divided into a first area and a second area, an active layer 130 formed on the first area of the n-type nitride semiconductor layer 120, a p-type nitride semiconductor layer 140 formed on the active layer 130, a p-type electrode 150 formed on the p-type nitride semiconductor layer 140, and an n-type electrode 160 formed on the second area of the n-type nitride semiconductor layer 120.

After then, a first metallic layer 310 is formed on the p-type electrode 150 and the n-type electrode 160 of the LED chip 100. At this time, it is preferable that the first metallic layer 310 includes reflection materials in order to prevent reflectivity of a submount to be described below from influencing a characteristic of the LED chip 100. For example, the first metallic layer 310 may be made of one or more metals selected from a group consisting of Sn, Cu, Au, Ag, and the like.

Subsequently, as shown in FIG. 4B, a submount 200 having high thermal conductivity is prepared.

After then, a second metallic layer 330 is formed on one surface of the submount 200 to be bonded to the LED chip 100. At this time, in the second metallic layer 320, an alloy containing Sn or Ag is formed in a paste form.

When the second metallic layer 330 is formed in the paste form as described above, it is possible to facilitate a bonding process in eutectic bonding to be described below in case that a surface of the submount 200 is uneven.

Then, the LED chip 100 and the submount 200 are eutectic-bonded by soldering the second metallic layer 330 and the first metallic layer 310 to each other (see FIG. 2).

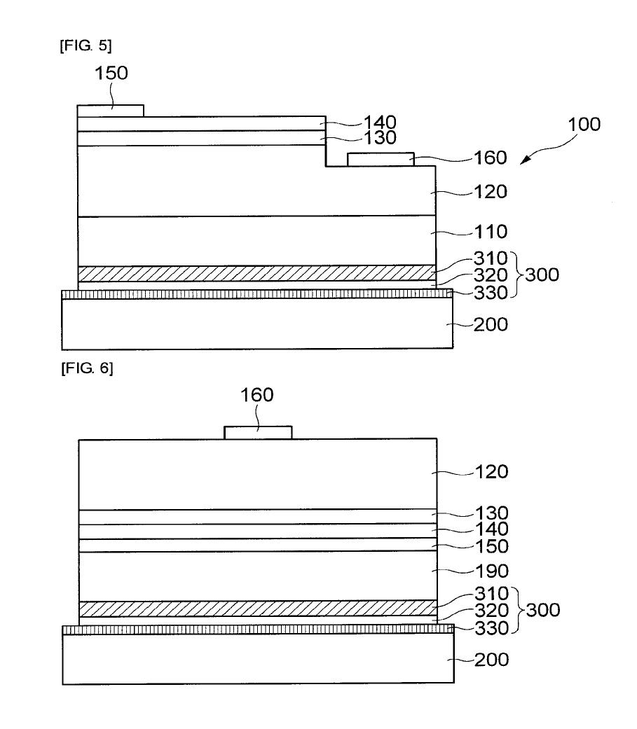

Meanwhile, in this embodiment, a flip chip type LED device which is one of horizontally structured LED devices among the GaN type LED devices has been described, but is not limited to it and may be applied to a top-emit type LED (see FIG. 5) and a vertically structured LED (see FIG. 6) formed to emit light through a p-type electrode layer being in contact with a p-type nitride semiconductor layer.

FIGS. 5 and 6 are schematic cross-sectional views of a GaN type LED device in accordance with another embodiment of the invention. FIG. 5 illustrates a structure of the top-emit type LED and FIG. 6 illustrates a structure of the vertically structured LED.

At this time, like reference numerals of the top-emit type LED and the vertically structured illustrated in FIGS. 5 and 6 refer to like elements shown in the flip chip type LED (see FIG. 2).

A reference numeral 190 undescribed in FIG. 6 represents a structure supporting layer.

In accordance with the invention, in an LED chip eutectic-bonded to a submount through an adhesive layer, the adhesive layer is configured by soldering each of a plurality of metallic layers which is a single element, it is possible to minimize a change in composition ratio of the alloy, and to reduce a thermal resistance and a leaked current.

Accordingly, the present invention can realize a GaN type LED device and a method of manufacturing the same, which can stabilize a thermal property, and improve a characteristic and reliability.

Although preferred embodiments of the present invention have been shown and described, it will be appreciated by those skilled in the art that changes may be made in these embodiments without departing from the principles and spirit of the general inventive concept, the scope of which is defined in the appended claims and their equivalents.

1-24. (canceled)

25. A method of manufacturing a GaN type LED device comprising the steps of:
preparing an LED chip;
forming a first metallic layer on a surface opposite to a light emitting surface of the LED chip;
preparing a submount;
forming a second metallic layer on one surface of the submount to be bonded to the LED chip; and
eutectic-bonding the first metallic layer and the second metallic layer to each other by soldering the first metallic layer and the second metallic layer,
wherein the second metallic layer is formed in a paste form.

26. The method according to claim 25, wherein the first metallic layer is made of the same material as the second metallic layer.

27. The method according to claim 25, wherein the first metallic layer is made of one or more metals selected from a group consisting of Sn, Ag, Au, and Cu.

28. The method according to claim 25, wherein the second metallic layer is made of an alloy containing Sn or Ag.

29. The method according to claim 25, further comprising the step of:
forming a transparent layer on the surface opposite to the light emitting surface of the LED chip, before the step of forming the first metallic layer on the surface opposite to the light emitting surface of the LED chip.

30. The method according to claim 29, wherein the transparent layer is made of one or more oxides selected from a group consisting of NiOₓ TiO₂, ITO, and SiO₂, or Si₃N₄ or MgF₂.

31. The method according to claim 29, further comprising the step of:
forming the reflection layer on the transparent layer after the step of forming the transparent layer on the surface opposite to the light emitting surface of the LED chip.

32. The method according to claim 31, wherein the reflection layer is made of an alloy containing at least one of Ag or Al.

33. The method according to claim 31, further comprising the step of:
forming a diffusion barrier layer on the reflection layer, after step of forming the reflection layer on the surface opposite to the light emitting surface of the LED chip.

34. The method according to claim 33, wherein the diffusion barrier layer is made of one or more metals selected from a group consisting of Ni, Pt, Cr, Ti, and W.

35. The method according to claim 25, wherein the LED chip includes:
a substrate;
an n-type nitride semiconductor layer formed on the substrate, which is divided into a first area and a second area;
an active layer formed on the first area of the n-type nitride semiconductor layer;
a p-type nitride semiconductor layer formed on the active layer;
a p-type electrode formed on the p-type nitride semiconductor layer; and
an n-type electrode formed on a second area of the n-type nitride semiconductor layer.

36. The method according to claim 25, wherein the LED chip includes:
an n-type electrode;
a light emitting structure formed by stacking the n-type electrode, the n-type nitride semiconductor layer, an active layer, and a p-type nitride semiconductor layer sequentially stacked on a bottom surface of the n-type electrode;
a p-type electrode formed on a bottom surface of the light emitting structure; and
a structure supporting layer formed on a bottom surface of the p-type electrode.
